(19) United States
(12) Patent Application Publication
(10) Pub. No.: US 2025/0056775 A1
(43) Pub. Date: Feb. 13, 2025

(54) HOUSING WITH SHIELDING FOR ELECTROMAGNETIC RADIATION

(71) Applicant: Continental Autonomous Mobility Germany GmbH, Ingolstadt (DE)

(72) Inventors: Stefan Heubusch, Buch (DE); Daniel Egger, Bernstadt (DE)

(73) Assignee: Continental Autonomous Mobility Germany GmbH, Ingolstadt (DE)

(21) Appl. No.: 18/720,752

(22) PCT Filed: Dec. 7, 2022
(86) PCT No.: PCT/DE2022/200293

§ 371 Date: Jun. 17, 2024

(30) Foreign Application Priority Data
Dec. 16, 2021 (DE) 10 2021 214 505.1

(51) Int. Cl. H05K 9/00

(52) U.S. Cl. CPC H05K 9/0045; H05K 9/0037

(57) ABSTRACT

An electronic device housing including at least one first and one second housing part, wherein the housing wall of at least the first housing part is formed from a plastic which is electrically non-conductive, wherein on the inside of the housing wall of at least the first housing part a metallization is provided which has a lattice-like or honeycomb-like structure and is formed from a plurality of intersecting metallization regions running in the longitudinal direction and transverse direction, and wherein the metallization is applied by a laser direct structuring process.

### CROSS-REFERENCE TO RELATED APPLICATIONS

The present application is a National Stage Application under 35 U.S.C. § 371 of International Application No. PCT/DE2022/200293 filed on Dec. 7, 2022, and claims priority from German Patent Application No. 102021214505.1 filed on Dec. 16, 2021, in the German Patent and Trade Mark Office, the disclosures of which are herein incorporated by reference in their entireties.

### BACKGROUND

### 1. Field

Embodiments of the present application relate to a housing with shielding for electromagnetic radiation.

### 2. Description of Related Art

Housings for electrical or electronic devices are already well-known in the prior art. Such devices have to meet EMC requirements (EMC: electromagnetic compatibility) specific to the particular application. In the event that electronic components which output electromagnetic radiation during operation are to be received in the housing, the housing can be used as a shielding device so that the electromagnetic radiation emitted to the outside by the electrical or electronic device is reduced. In addition, the shielding device occasions EMC protection of the electrical or electronic device against electromagnetic radiation which acts on the device from outside. Such housings are in particular utilized in the automotive sector.

Housings having shielding properties for electromagnetic radiation can be produced, for example, from metal. The problem of metallic housings is that these are heavy and expensive. Furthermore, metallic housings restrict the design flexibility.

### SUMMARY

Proceeding herefrom, objects and aspects of the present application relate to a housing which has, on the one hand, shielding properties for electromagnetic radiation but, on the other hand, does not weigh much, can be manufactured inexpensively and offers great flexibility in the housing design.

According to a first aspect of an embodiment, there is provided a housing for an electrical or electronic device, said housing comprising at least one first and one second housing part is disclosed. The housing wall of at least the first housing part is formed from a plastic which is electrically non-conductive. On the inside of the housing wall of at least the first housing part, a metallization is provided which has a lattice-like or honeycomb-like structure and is formed from a plurality of intersecting metallization regions running in the longitudinal direction and transverse direction. For example, the longitudinal axes of a first part of the metallization regions are aligned parallel to one another so that the metallization regions run in a first spatial direction and are arranged at a distance from one another. The longitudinal axes of a second part of the metallization regions are, for example, likewise aligned parallel to one another so that the metallization regions run in a second spatial direction and are arranged at a distance from one another. The second spatial direction runs transversely, in particular perpendicularly, to the first spatial direction. As a result, the metallization has regions in which no metallization is provided. These regions are also referred to as meshes. The meshes can have a rectangular, square, polygonal or round or oval shape. The metallization is applied by a laser direct structuring process.

The technical advantage of the housing is that a plastic housing is provided which has a high shielding effect in terms of radiation emitted from the housing, but also in terms of electromagnetic radiation incident in the interior of the housing, offers great design flexibility and, furthermore, can be manufactured easily and inexpensively due to the fact that plastic is used as the static load-bearing housing material.

According to an aspect of an exemplary embodiment, the first housing part is configured in a troughlike manner, wherein the metallization extends from a bottom portion via a side wall portion up to a circumferential housing shoulder or housing flange which runs parallel or substantially parallel to the bottom portion. Thanks to this course of the metallization, a comprehensive shielding effect of the housing part upwards and towards the sides is achieved, on the one hand, and thanks to the fact that the printed circuit board rests on the housing shoulder or housing flange, the metallization can be electrically contacted with the ground potential of the printed circuit board, on the other hand, without having to establish a separate ground connection.

According to an aspect of an exemplary embodiment, the housing shoulder or housing flange has multiple screw openings and is configured to form a bearing surface for the second housing part and/or a printed circuit board to be arranged in the housing. The fact that the printed circuit board rests on the housing shoulder or housing flange and the second housing part is screwed to the first housing part means the printed circuit board is clamped between the housing parts and, as a result, fixed.

The metallization of the first housing part preferably extends into the screw openings in order to be able to establish an electrical contact between the first and second housing parts via the screws which can be screwed into the screw openings. This is in particular advantageous if the second housing part also has a metallization or is formed from metal.

According to an aspect of an exemplary embodiment, the first housing part is divided into multiple partial regions. The metallization has different mesh sizes and/or different metallization thicknesses in the partial regions. The mesh size is in particular adapted to the frequency of the components which are provided in the respective partial region of the housing. Thus, the mesh size can be selected to be larger, for example, in a first housing part in which components are provided which emit low-frequency radiation or are susceptible to interference from low-frequency radiation, than in a partial region of the housing in which components are provided which emit high-frequency radiation or are susceptible to interference from high-frequency radiation. The metallization thickness can be selected such that the layer thickness of the metallization in partial regions in which components having a high frequency or components susceptible to interference from high-frequency radiation are provided is less than in regions having components which are operated at a lower frequency or which are susceptible to interference from low-frequency radiation.

According to an aspect of an exemplary embodiment, the partial regions are separated from one another by at least one wall portion, wherein the wall portion at least partially has the metallization. As a result, the respective partial regions of the housing are also shielded with respect to one another against the penetration of electromagnetic radiation from the other partial region in each case.

According to an aspect of an exemplary embodiment, the lattice-like structure has square, rectangular, polygonal, round or oval meshes. The shape of the mesh can be adapted to the respective area of application and the respective shape of the housing. A mixture of different mesh shapes is also in principle possible.

According to an aspect of an exemplary embodiment, the mesh size of the lattice-like structure is selected such that the opening width of a mesh is smaller or equal to λ/10, wherein λ is the wavelength of the electromagnetic radiation which is emitted by an electronic component to be received in the housing or which can lead to interference of the electronic component due to radiation from outside. This size dimensioning makes it possible to achieve a good shielding effect of the housing to the outside and, at the same time, to achieve a material saving compared with metallization over the entire surface.

According to an aspect of an embodiment, there is provided an arrangement consisting of a housing and a printed circuit board which has at least one electronic component. The housing comprises a first and a second housing part, wherein the printed circuit board is received in a region between the first and second housing parts. The housing wall of at least the first housing part is formed from a plastic which is electrically non-conductive. On the inside of the housing wall of at least the first housing part a metallization is provided which has a lattice-like or honeycomb-like structure and is formed from a plurality of intersecting metallization regions running in the longitudinal direction and transverse direction. The metallization is applied by a laser direct structuring process.

The technical advantage of the arrangement is that a printed circuit board can be received in an electrically shielded manner in the plastic housing, wherein the plastic housing has a high shielding effect in terms of radiation emitted from the housing, but also in terms of electromagnetic radiation incident in the interior of the housing. Furthermore, the housing offers great design flexibility and can be manufactured easily and inexpensively due to the fact that plastic is used as the static load-bearing housing material.

According to an aspect of an exemplary embodiment of the arrangement, the printed circuit board is held clamped between the first and second housing parts. As a result, the printed circuit board can be mechanically fixed in the housing, on the one hand, and the metallization of the housing part can be electrically contacted with the printed circuit board, on the other hand, in order to prevent the metallization becoming electrostatically charged.

According to an aspect of an exemplary embodiment, the metallization of the first housing part extends from a bottom portion via a side wall portion up to a circumferential housing shoulder or housing flange which runs parallel or substantially parallel to the bottom portion. Thanks to this course of the metallization, the fact that the printed circuit board rests on the housing shoulder or housing flange means that the metallization can be electrically contacted with the ground potential of the printed circuit board, without having to establish a separate ground connection.

According to an aspect of an exemplary embodiment, the printed circuit board lies on the edge of the housing shoulder or housing flange of the first housing part. The printed circuit board preferably lies on the edge circumferentially. As a result, an advantageous mounting of the printed circuit board in the housing can be achieved.

In addition, the printed circuit board is preferably also supported by at least one wall region which extends upwards from the bottom portion of the housing.

According to an aspect of an exemplary embodiment, the printed circuit board has, on the side facing the housing shoulder, at least in sections, a metallization which forms a connection to ground. As a result of the printed circuit board resting on the edge of the housing shoulder of the first housing part, the metallization of the first housing part is electrically connected to the metallization of the printed circuit board. As a result, the metallization of the first housing part can be coupled to the ground potential of the printed circuit board in a technically simple manner via the metallization of the printed circuit board.

According to an aspect of an exemplary embodiment, the metallization of the printed circuit board extends in a lattice-like manner or over the entire surface or substantially over the entire surface of the printed circuit board and is configured to form shielding against the escape of electromagnetic radiation from the housing through the printed circuit board. In other words, the first housing part forms, together with the printed circuit board, shielding which is completely or substantially completely closed on the circumferential side, which shielding prevents electromagnetic radiation from escaping.

According to an aspect of an exemplary embodiment, the at least one electronic component is arranged on the side of the printed circuit board which faces the first housing part having the lattice-like metallization. Thanks to this arrangement of the component, shielding can be achieved by metallization of the printed circuit board, which shielding makes a shielding effect obsolete in the case of the second housing part. However, in order to increase the shielding effect, the second housing part can additionally have a lattice-like or honeycomb-like metallization or can be formed from a metal.

According to an aspect of an exemplary embodiment, the lattice-like or honeycomb-like structure has square, rectangular, polygonal, round or oval meshes. The mesh size of the lattice-like or honeycomb-like structure is selected such that the opening width of a mesh is smaller or equal to λ/10, wherein λ is the wavelength of the electromagnetic radiation which is emitted by the electronic component to be received in the housing or which can lead to interference of the electronic component due to radiation from outside. This size dimensioning makes it possible to achieve a good shielding effect of the housing to the outside and, at the same time, to achieve a material saving compared with metallization over the entire surface.

According to an aspect of an exemplary embodiment, the first housing part is divided into multiple partial regions. The metallization has different mesh sizes and/or different metallization thicknesses in the partial regions. The mesh size is adapted in particular to the components which are provided in the respective partial region of the housing. Thus, the mesh size can be selected to be larger, for example, in a first housing part in which components are provided which emit low-frequency radiation or are susceptible to interference from low-frequency radiation, than in a partial region of the housing in which components are provided which emit high-frequency radiation or are susceptible to interference from high-frequency radiation. The metallization thickness can be selected such that the layer thickness of the metallization in partial regions in which components having a high frequency or components susceptible to interference from high-frequency radiation are provided is less than in regions having components which are operated at a lower frequency or which are susceptible to interference from low-frequency radiation.

Within the meaning of the invention, the expressions “approximately”, “substantially” or “roughly” mean deviations from the exact value in each case by +/−10%, preferably by +/−5%, and/or deviations in the form of changes which are insignificant to the function.

Further developments, advantages and possible applications of the invention are set out by the following description of exemplary embodiments and by the figures. All of the features described and/or pictured per se or in any combination are in principle the subject-matter of the invention, irrespective of their combination in the claims or references back thereto. The content of the claims is also made an integral part of the description.

### BRIEF DESCRIPTION OF THE DRAWINGS

Object and aspects of the exemplary embodiments are explained in more detail below with reference to the figures, in which:

FIG. 1 shows, by way of example, a perspective view of an electrical or electronic device;

FIG. 2 shows, by way of example, the electrical or electronic device in an exploded view;

FIG. 3 shows, by way of example, the first section identified in FIG. 2 with the reference numeral A1 in a detailed view;

FIG. 4 shows, by way of example, the second section identified in FIG. 2 with the reference numeral A2 in a detailed view;

FIG. 5 shows, by way of example, a cross-sectional view through the electronic device in order to illustrate the sandwich structure;

FIG. 6 shows, by way of example, a cross-sectional view through a first embodiment of the electronic device, with the shielded region being identified by the rectangle drawn with dashed lines, and

FIG. 7 shows, by way of example, a cross-sectional view through a second embodiment of the electronic device, with the shielded region being identified by the rectangle drawn with dashed lines.

### DETAILED DESCRIPTION

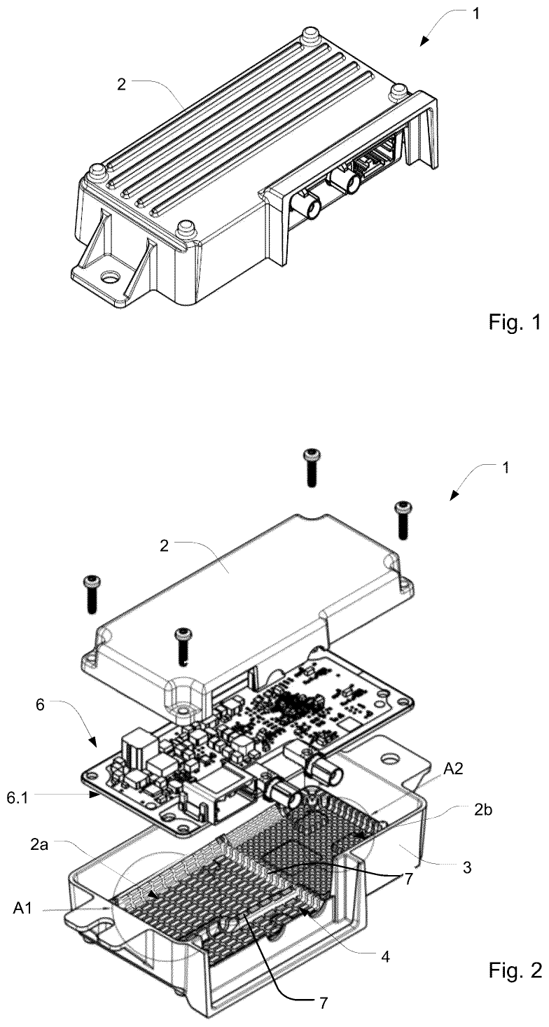

FIG. 1 shows, by way of example, a housing 1 of an electronic device. The electronic device can, for example, be a control unit of a vehicle. The housing comprises a first and a second housing part 2 which can be detachably connected to one another by means of screw connections. The housing wall of at least the first housing part 2 is formed from an electrically non-conductive plastic. In particular, this means that the wall of the first housing part 2, except from a metallization on the surface, consists of plastic.

The housing 1 is provided to receive electronic components, by means of which the functionality of the electronic device is occasioned. In addition, apertures for interfaces or electrical connections can be provided on the housing, as shown in FIG. 1, to which electrical lines can be connected, for example.

FIG. 2 shows the electronic device in an exploded view, wherein the view in FIG. 2 is an overhead view, i.e. the first housing part 2 shown in FIG. 1, which forms an upper housing part when the device is installed, is depicted at the bottom in FIG. 2.

At least one printed circuit board 6, which is held clamped between the first and second housing parts 2, 3, is provided in the housing 1. The printed circuit board 6 has a plurality of electronic components in order to achieve the desired functionality of the electronic device.

It is known that electromagnetic radiation is emitted by electronic components during their operation. In order to prevent the device from outputting electromagnetic radiation above a target threshold value to the outside, the housing 1 has an electromagnetic shielding device.

The shielding device is formed by a metallization 4 which is provided on the inside of at least the first housing part 2. The metallization 4 is not applied to the entire surface of the inside of the first housing part 2, but rather has a lattice-like or honeycomb-like structure. In other words, the metallization consists of a plurality of intersecting metallization regions 4.1 which run, for example, in two different spatial directions. The metallization regions 4.1 are arranged at a distance from one another such that between neighboring metallization regions 4.1 there are openings or meshes, in which no metallization is provided. The meshes can have a square, rectangular, polygonal or round or oval cross-sectional form.

The metallization is applied to the inner wall of the first housing part 2 by means of a laser direct structuring process (LDS process). The laser direct structuring process utilizes, for example, a thermoplastic material which is doped with a (non-conductive) laser-activatable metal compound as a plastic additive. The first housing part is manufactured, for example, in an injection-molding process. The inside of the first housing part 2 is subsequently treated with a laser beam, wherein the laser acts on those regions to which a metallization is to subsequently be applied. When the laser beam hits said plastic, the surface of the plastic matrix can be decomposed into volatile cleavage products and metal nuclei can be split off from the plastic additive, which come to lie near the surface. Said metal particles catalyze, for example, the subsequent chemically reductive copper metallization.

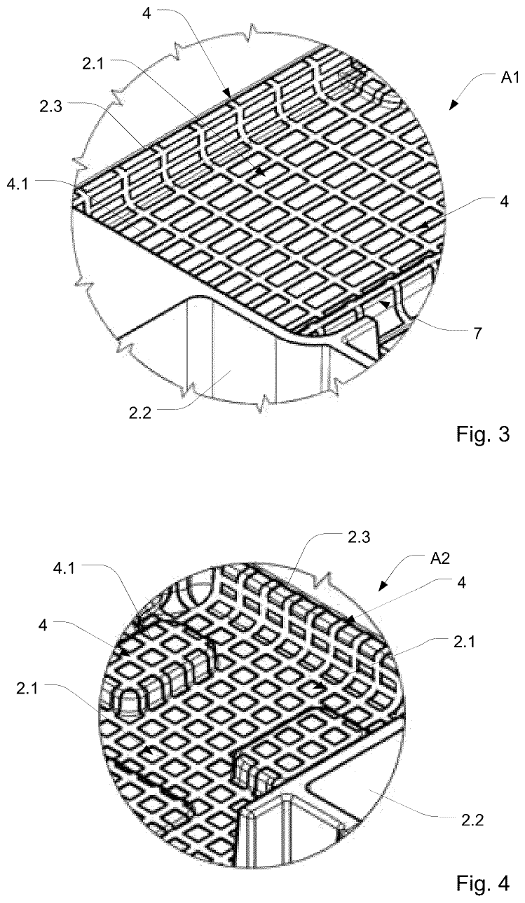

As can be seen in FIG. 2 and the detailed views according to FIGS. 3 and 4, the first housing part 2 is configured in a troughlike manner. It has a bottom portion 2.1, a circumferential side wall portion 2.2 protruding from the bottom portion 2.1 and a housing shoulder 2.3. The housing shoulder 2.3 is, for example, configured in a steplike manner and forms a horizontal bearing surface running parallel to the bottom portion 2.1, in particular a circumferential bearing surface for the printed circuit board 6, so that the edge of the printed circuit board 6 rests on the housing shoulder 2.3.

The lattice-like or honeycomb-like metallization extends from the bottom portion 2.1 via the side wall portions 2.2 up to the housing shoulder 2.3.

Preferably, the printed circuit board 6 likewise has a metallization 6.1, at least at the edge in the region which comes to rest with respect to the housing shoulder 2.3. This metallization 6.1 is connected to a ground connection of the electrical or electronic device. As a result, when the printed circuit board 6 rests on the housing shoulder 2.3, an electrically conductive connection is established between the metallization 4 of the first housing part 2 and the metallization 6.1 of the printed circuit board 6, and the metallization 4 of the first housing part 2 is therefore also connected to the ground connection. As a result, the metallization 4 can be prevented from becoming electrically charged.

The mesh size of the metallization 4 is preferably adapted to the frequency of the electromagnetic radiation which is emitted by the electronic component. Mesh size is understood to mean in particular the largest opening width measured in a straight line. In the case of a rectangular or square opening in the metallization 4, this is the opening width measured diagonally. The mesh size is selected such that the latter is at most one tenth of the wavelength λ of the electromagnetic wave (i.e., 1/10*λ) which is emitted by the electronic component.

In the event that multiple different circuit parts which operate at different frequencies (for example, a low-frequency circuit part and a high-frequency circuit part) and therefore emit different wavelengths are provided on the printed circuit board 6, the metallization 4 can have different mesh sizes in partial regions 2a, 2b of the housing 1. The mesh sizes are then adapted, in each case, to the frequency of the circuit part which is received in the respective partial region 2a, 2b of the housing 1.

The partial regions 2a, 2b of the housing 1 can be separated from one another by one or more wall portions 7. The at least one wall portion 7 protrudes at an angle from the bottom portion 2.1 and therefore forms a wall-like elevation, by means of which the partial regions 2a, 2b are delimited from one another. The wall portion preferably likewise has the metallization and therefore prevents electromagnetic waves from being able to propagate, in an undampened manner, between the partial regions 2a, 2b of the housing 1.

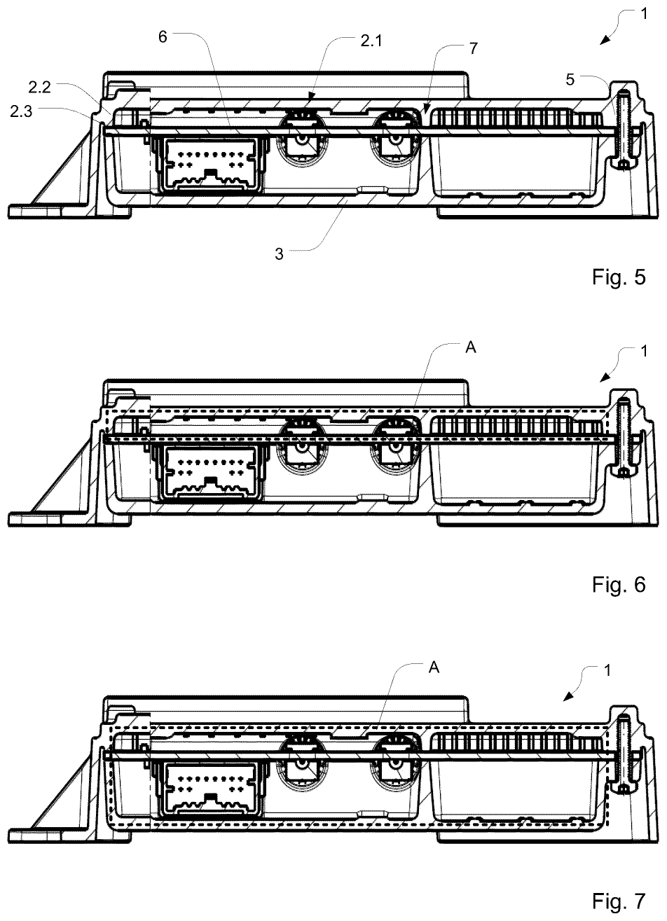

FIGS. 5 and 6 show, by way of example and diagrammatically, a section through the housing of FIG. 2 in an assembled state.

As can be seen in the figures, the printed circuit board 6 is held clamped between the housing parts 2, 3, which are screwed together, for example. The electromagnetic shielding A of the housing 1 can either be achieved by the first housing part 2 itself, together with the printed circuit board 6, i.e., the second housing part 3 does not have any shielding for electromagnetic radiation, or the shielding A is achieved by the combination of the first and second housing parts 2, 3 which are both configured to shield against electromagnetic radiation.

In FIG. 6, the dashed line indicates which housing region is provided with the shielding A. The printed circuit board 6 is preferably fitted with electronic components on one side and indeed such that these face the first housing part 2 in the assembled state of the electrical or electronic device.

In order to shield against the electromagnetic radiation which is caused by these electronic components, the printed circuit board 6 has, in the exemplary embodiment according to FIG. 6, a continuous or substantially continuous shielding layer. The emission of electromagnetic radiation in the direction of the second housing part 3 is prevented by said shielding layer. In this case, the second housing part 3 can be formed without a shielding effect, for example as a pure plastic housing part without a metallization layer on the inside. Alternatively, the second housing part 3 can be formed from a metal. As a result, the emission of electromagnetic radiation can be further reduced.

The shielding layer of the printed circuit board 6 is preferably coupled to the ground connection of the electronic circuit which is provided on the printed circuit board 6. As a result, no potential can build up on the shielding layer due to the electromagnetic radiation. As explained above, the shielding layer of the printed circuit board 6 can be electrically connected to the metallization 4 of the first housing part 2 so that the metallization 4 is coupled to the ground connection via the shielding layer of the printed circuit board 6.

In the exemplary embodiment of FIG. 7—in contrast to the exemplary embodiment of FIG. 6—the printed circuit board 6 is not used as the shielding plane, but rather the housing 1 as a whole, i.e., the first and second housing parts 2, 3 are configured as housing parts which shield against electromagnetic radiation. The first and second housing parts 2, 3 are preferably configured as plastic housing parts and have a lattice-like or honeycomb-like metallization on the inside, which produces the shielding effect.

The metallization of the first housing part 2 is preferably configured such that the metallization 4 extends into the screw openings 5 of the first housing part 2. The screw openings 5 are provided with an internal thread, for example, and the internal thread has a metallization at least in sections. As a result, an electrically conductive connection can be established between the first and second housing parts 2, 3 via the screws, by means of which the housing parts 2, 3 are screwed together.

The invention has been described above using exemplary embodiments. It goes without saying that numerous changes as well as modifications are possible without leaving the scope of protection defined by the claims.

1. A housing for an electronic device, the housing comprising:
a housing part formed from a plastic that is electrically non-conductive, wherein the housing part comprises a metallization mesh provided on an interior surface of the housing part.

2. The housing according to claim 1, wherein the housing part is configured in a troughlike manner, wherein on the interior surface of the housing part the metallization mesh extends from a bottom portion via a side wall portion up to a circumferential housing shoulder or housing flange which runs parallel or substantially parallel to the bottom portion.

3. The housing according to claim 2, further comprising multiple screw openings disposed in the housing shoulder,
wherein the housing shoulder is configured to form a bearing surface for the electronic device to be arranged in the housing.

4. The housing according to claim 3, wherein the housing part comprises multiple partial regions and the metallization mesh has different mesh sizes and/or different thicknesses in the multiple partial regions.

5. The housing according to claim 4, further comprising a wall portion separating the multiple partial regions.

6. The housing according to claim 5, wherein the mesh is square, rectangular, polygonal, round or oval.

7. The housing according to claim 6, wherein an opening width of the mesh is smaller or equal to λ/10, wherein λ is the wavelength of electromagnetic radiation emitted by the electronic device.

8-15. (canceled)
